(19) United States
(12) Patent Application Publication
(10) Pub. No.: US 2026/0129804 A1
(43) Pub. Date: May 7, 2026

(54) HIGH SPEED, HIGH DENSITY I/O CONNECTOR ASSEMBLY

(71) Applicant: Amphenol Corporation, Wallingford, CT (US)

(72) Inventors: Xingye Chen, Markham (CA); Omer Khan, Bowmanville (CA); R. Brad Brubaker, Etters, PA (US); Galen Liu, Shenzhen (CN); Guoxun Huang, Shenzhen (CN); Qigui Xu, Shenzhen (CN)

(73) Assignee: Amphenol Corporation, Wallingford, CT (US)

(21) Appl. No.: 19/369,518

(22) Filed: Oct. 27, 2025

(30) Foreign Application Priority Data
Nov. 1, 2024 (CN) 202411554088.1
Nov. 1, 2024 (CN) 202422668103.7

(51) Int. Cl. H05K 7/20; H01R 12/70; H01R 12/71; H01R 13/53; H01R 13/533

(52) U.S. Cl. CPC H05K 7/20418; H01R 12/7076; H01R 12/712; H01R 13/53; H01R 13/533; H01R 2201/06

(57) ABSTRACT

High speed, high density I/O connector assemblies. An I/O connector assembly includes a cage and a heat dissipation member. The cage includes a top wall having an opening and a channel accessible from the front. The heat dissipation member includes a base disposed at the top of the cage, multiple sections separated by gaps, and a contact portion protruding from the base in a first direction into the channel through the opening of the top wall. Each section includes fins protruding from the base in a direction opposite to the first direction. The heat dissipation member comprises a layer of micro thermal interface material at a contact interface. Techniques described herein, including the structure and material composition of components, can provide sufficient heat dissipation to enable high speed, high density I/O connector assemblies that nonetheless can be economically manufactured and meet the dimensional requirements of an OSFP-XD standard.

### CROSS-REFERENCE TO RELATED APPLICATIONS

This application claims priority to and the benefit of Chinese Patent Application No. 202422668103.7, filed on Nov. 1, 2024. This application also claims priority to and the benefit of Chinese Patent Application No. 202411554088.1, filed on Nov. 1, 2024. The contents of these applications are incorporated herein by reference in their entirety.

### TECHNICAL FIELD

The present disclosure relates generally to interconnection systems, such as those including electrical connectors, used to interconnect electronic assemblies.

### BACKGROUND

Electronic devices are often connected, whether to enable those devices to communicate over networks or because those devices form part of the network. For example, servers are often connected to a network to exchange data with other servers or end user devices. Similarly, routers and switches are often connected to form a network or connected to devices that are using the network to exchange data.

Often such connections are made through I/O connectors (input/output connectors) inside the devices mated with plug connectors terminating cables. The I/O connectors are configured as receptacle connectors that mount to a circuit board and mate with a plug connector. The receptacle connectors may be mounted near an edge of a circuit board to which components forming the electronic device are attached. That edge may be next to a panel of an enclosure holding the circuit board and possibly other subassemblies that constitute the electronic device.

To enable a plug connector to be inserted into a receptacle connector, the panel may have openings through which a plug connector may be inserted to mate with the receptacle connector. Receptacle connectors are often enclosed in a grounded metal structure, referred to as a cage. The cage may have one or more channels, each shaped to receive a plug connector and aligned with both a panel opening and a mating interface of a receptacle connector. The plug connector may be inserted through the panel opening into the channel, such that the plug connector and receptacle connector mate inside the cage. In this state, the cage blocks radiation from inside the device from reaching the panel opening. Further, the plug connector may have a conductive exterior that is also grounded, which blocks radiation from the plug connector or the receptacle connector from exiting the cage through the channel. The cages, plug connectors and receptacle connectors are often made according to industry standards such as an OSFP standard.

For making connections that carry data at high data rates, the plug connector may include a transceiver that converts signals in a format transmitted over the cable into a format that may be used inside the device. The transceiver may generate heat, which may be dissipated by a cooling fan, pulling air through or around the cage.

### SUMMARY

Aspects of the present disclosure relate to high speed, high density I/O connector assemblies.

Some embodiments relate to a connector assembly. The connector assembly may comprise a cage comprising walls at a top, bottom, sides and rear of the cage, and a port at a front of the cage and configured to enable access to a channel defined by the wall of the cage, the wall at the top of the cage having an opening; and a heat dissipation member comprising a base disposed at the top of the cage, a plurality of sections separated by gaps, and a contact portion protruding from the base in a first direction into the channel through the opening of the wall at the top of the cage. Each of the plurality of sections may comprise a plurality of fins protruding from the base in a second direction opposite to the first direction; and the heat dissipation member may comprise a layer of micro thermal interface material at the contact portion.

Optionally, the cage may have dimensions according to an OSFP-XD standard.

Optionally, each of the plurality of sections may have ten fins protruding from the base in a second direction opposite to the first direction; and both the base and the fins may comprise die cast metal.

Optionally, each fin may have a height in the range of 18 to 22 mm in the second direction.

Optionally, the heat dissipation member may extend to the wall at the rear of the cage.

Optionally, the cage may comprise a copper alloy and a nickel silver plating on the copper alloy; and the heat dissipation member may comprise an aluminum alloy and a nickel plating on the aluminum alloy.

Optionally, the connector assembly may further comprise a clip comprising strips disposed in the gaps between the plurality of sections of the heat dissipation member and bars connecting the strips and attached to the walls at the sides of the cage, and the clip may comprise stainless steel.

Optionally, each of the plurality of sections of the heat dissipation member may comprise a first segment and a second segment and a space therebetween; the first segment and the second segment may comprise an equal number of fins; the spaces of the plurality of sections of the heat dissipation member are aligned; and the connector assembly may further comprise a light pipe having a first end disposed at the rear of the cage, a second end extending beyond the heat dissipation member, and a body extending from the first end to the second end through the aligned spaces of the plurality of sections of the heat dissipation member.

Optionally, the connector assembly may further comprise a support member attached to the wall at the rear of the cage and holding the first end of the light pipe.

Optionally, the support member may comprise a body having a groove for holding the first end of the light pipe and a latch extending from the body and hooked to the wall at the rear of the cage.

Optionally, both the body and the second end of the light pipe may comprise extensions disposed on the wall at the top of the cage.

Optionally, the wall at the top of the cage may comprise a region having a plurality of holes; and the heat dissipation member may extend to the region and end before the wall at the rear of the cage.

Some embodiments relate to a connector assembly. The connector assembly may comprise a cage comprising outer walls at a top, bottom, sides and rear of the cage, inner walls disposed parallel to the outer walls at the sides and dividing interior of the cage into a plurality of channels, and a plurality of port aligned at a front in a row direction and configured for accessing to a plurality of channels; and a light pipe assembly attached to the outer wall at the side of the cage, the light pipe assembly comprising a plurality of light pipes each having a first end adjacent the bottom of the cage and a second end adjacent the front of the cage, the second ends of the plurality of light pipes aligned in a column direction perpendicular to the row direction, the first ends of the plurality of light pipes aligned in a mating direction perpendicular to both the row direction and the column direction.

Optionally, the light pipe assembly may comprise: a first rod connecting the first ends of the plurality of light pipes; a second rod connecting the second ends of the plurality of light pipes; and a third rod extending from a light pipe of the plurality of light pipes and attached to the outer wall at the side of the cage.

Optionally, the light pipes of the light pipe assembly may comprise clear polycarbonate.

Optionally, the cage may have dimensions according to an OSFP-XD standard.

Optionally, the outer wall at the top of the cage may comprise a plurality of openings above respective channels of the plurality of channels; and the connector assembly may further comprise: a plurality of heat dissipation members, each of which may comprise a base disposed at the top of the cage, and a contact portion protruding from the base in a first direction into a respective channel of the plurality of channels through a respective opening of the plurality of openings.

Optionally, the cage may comprise a copper alloy and a nickel silver plating on the copper alloy; and each of the plurality of the heat dissipation members may comprise an aluminum alloy, a nickel plating on the aluminum alloy, and a layer of micro thermal interface material at the contact portion.

Optionally, each of the heat dissipation members may have a plurality of sections separated by gaps, each of the plurality of sections comprising a plurality of fins protruding in a second direction opposite to the first direction; and the connector assembly may further comprise a clip comprising strips disposed in the gaps between the plurality of sections of the plurality of heat dissipation members and bars connecting the strips and attached to the outer walls at the sides of the cage.

Some embodiments relates to an electronic device. The electronic device may comprise: a chassis comprising a panel having one or more openings; a circuit board disposed in the chassis; and a connector assembly mounted on the circuit board. The connector assembly may comprise: a cage comprising a plurality of ports aligned in a row direction and with the one or more openings of the panel of the chassis, and a plurality of light pipes, each of the plurality of light pipes comprising a first end facing a surface of the circuit board and aligned in a mating direction, a second end adjacent the one or more openings of the panel of the chassis and aligned in a direction perpendicular to both the row direction and the mating direction. The number of the plurality of light pipes may be configured to equal to the number of the plurality of ports of the cage.

Optionally, the circuit board may comprise a first surface and a second surface opposite the first surface; the connector assembly is a first connector assembly mounted on the first surface of the circuit board; and the electronic device may further comprise a second connector assembly mounted on the second surface of the circuit board.

Optionally, the second connector assembly may comprise: a cage comprising a plurality of ports aligned in the row direction; a plurality of light pipes, each of which comprising a first end facing the second surface of the circuit board and aligned in the mating direction, a second end aligned in a column direction perpendicular to both the row direction and the mating direction; and the plurality of light pipes of the first connector assembly and the plurality of light pips of the second connector assembly are disposed on opposite sides of the one or more openings of the chassis.

Some embodiments relate to a connector assembly. The connector assembly may comprise a cage comprising a plurality of ports aligned in a row direction; a plurality of heat dissipation members, each of the plurality of heat dissipation members comprising a base disposed at a top of the cage; and a plurality of light pipes, each of the plurality of light pipes comprising a first end aligned in a mating direction, and a second end adjacent the plurality of ports of the cage and aligned in a column direction perpendicular to both the row direction and the mating direction,

Optionally, a number of the plurality of light pipes is configured to be equal to a number of the plurality of ports of the cage.

These techniques may be used alone or in any suitable combination. The foregoing summary is provided by way of illustration and is not intended to be limiting.

### BRIEF DESCRIPTION OF THE DRAWINGS

The accompanying drawings are not intended to be drawn to scale. In the drawings, each identical or nearly identical component that is illustrated in various figures may be represented by a like numeral. For purposes of clarity, not every component may be labeled in every drawing. In the drawings,

FIG. 1 is a perspective view of an electronic device, partially exploded and partially cut away, with an I/O connector assembly, according to some embodiments.

FIG. 2 is a perspective view of the connector assembly of FIG. 1 and a transceiver configured as a plug positioned for insertion into a channel of a cage of the connector assembly of FIG. 1.

FIG. 3A is a perspective view of an I/O connector assembly that may be used in the electronic device of FIG. 1, with a heat dissipation member attached to a cage by a clip, according to some embodiments.

FIG. 3B is a partially exploded perspective view of the connector assembly of FIG. 3A.

FIG. 4A is a top perspective view of the heat dissipation member of the connector assembly of FIG. 3A.

FIG. 4B is a bottom perspective view of the heat dissipation member of FIG. 4A.

FIG. 5A is a perspective view of a connector assembly that may be used in the electronic device of FIG. 1, with a heat dissipation member attached to a cage by a clip and a light pipe at a top, according to some embodiments.

FIG. 5B is a perspective view of the connector assembly of FIG. 5A, with the heat dissipation member and clip hidden.

FIG. 5C is partially exploded perspective view of the connector assembly of FIG. 5B.

FIG. 6A is a perspective view of a connector assembly that may be used in the electronic device of FIG. 1, with heat dissipation members attached to a cage by a clip and respective top light pipes, according to some embodiments.

FIG. 6B is a partially exploded perspective view of the connector assembly of FIG. 6A.

FIG. 7 is a side elevation view of the connector assembly of FIG. 5A or 6A used in a belly-to-belly configuration, according to some embodiments.

FIG. 8A is a perspective view of a connector assembly that may be used in the electronic device of FIG. 1, with a light pipe assembly, according to some embodiments.

FIG. 8B is a perspective view of an outer side of the light pipe assembly of the connector assembly of FIG. 8A.

FIG. 8C is a perspective view of a second side of the light pipe assembly of FIG. 8B opposite the first side.

FIG. 9 is a side elevation view of the connector assembly of FIG. 8A used in a belly-to-belly configuration, according to some embodiments.

FIG. 10A is a perspective view of an I/O connector assembly that may be used in the electronic device of FIG. 1, with the heat dissipation members attached to a cage by a clip and a light pipe assembly, according to some embodiments.

FIG. 10B is a partially exploded perspective view of the connector assembly of FIG. 10A.

FIG. 11 is a side elevation view of the connector assembly of FIG. 10A used in a belly-to-belly configuration, according to some embodiments.

### DETAILED DESCRIPTION

The inventors have recognized and appreciated high speed, high density connector assemblies for input or output (“I/O connector assemblies”) that include cages. High speed connector assemblies require more electronic circuitry per channel, which can generate more heat. Further, for high density, circuitry may be confined to a small space, which is bounded by a cage. The cage tends to trap the generated heat, which may lead to an unacceptable temperature rise. Moreover, the desire to provide compact electronic devices precludes arbitrarily adding or increasing the size of the components that dissipate heat. These increasing power density and thermal requirements of I/O connectors present challenges in designing connector assemblies.

For example, OSFP-XD supports higher data rates, often up to 800 Gbps, which generates more heat during operation. Additionally, the larger form factor of OSFP-XD presents challenges for designing panels. Techniques described herein, including the structure and material composition of components, can provide sufficient heat dissipation to enable high speed, high density connector assemblies that nonetheless can be economically manufactured and meet the dimensional requirements of an OSFP-XD standard. As used herein, the term “OSFP-XD standard” refers to the standard in effect as of the filing date of the priority applications (i.e., Nov. 1, 2024), and encompasses any versions of the standard issued prior thereto.

According to aspects of the present application, an I/O connector assembly may include a receptacle connector inside a cage. Both the receptacle connector and the cage may be mounted on a circuit board. The receptacle connector may be configured to support high data rates, such as data rates according to the OSFP-XD or other standard. The cage may include a channel enclosed by walls at a top, bottom, sides and rear, with a port at a front for accessing to the channel. The receptacle connector may be disposed adjacent the rear wall of the cage. During operation, a plug connector may be inserted into the channel to mate with the receptacle connector so as to connect to circuits on the circuit board.

The cage may include an opening at the top wall. The connector assembly may include a heat dissipation member. The heat dissipation member may include a base disposed on the top wall of the cage. A contact portion of the heat dissipation member configured for contacting a mating plug connector inside the cage may protrude from the base in a first direction into the channel through the opening of the top wall. The contact portion may include a layer of micro thermal interface material at a contact portion interfacing with a mating plug connector. Such micro thermal interface material may be formulated to enhance thermal performance and durability of heat generating devices, such as the plug connector and the heat dissipation member. Examples of such a micro thermal interface material include BERGQUIST® microTIM mTIM 4028. Such a configuration may provide robustness and resilience to the repeated pull and plug action of insertion devices while delivering good thermal impedance.

One or more sections of fins may protrude from the base in a second direction opposite to the first direction. Optionally, the fins may extend to the rear wall of the cage, which may provide optimized heat dissipation for some implementations according to the OSFP-XD standard. In some embodiments, each section may include fins between nine and eleven, such as ten fins, which may provide high heat dissipation for some implementations according to the OSFP-XD standard, considering space and cost constraints. High heat dissipation may be characterized by operating temperatures at locations such as the top of the cage, the bottom of the cage, the mating interface between a plug connector and a receptacle connector, and the like.

Optionally, the fins and the base of the heat dissipation member may be integrally formed. In some embodiments, the heat dissipation member may be economically formed of die cast metal, and the number of fins may be selected to accommodate a desired rate of heat dissipation while adhering to size constraints and manufacturability constraints on the die casting process. In some examples the fins may extend above the top wall of the cage by an amount that provides a desired amount of heat dissipation while nonetheless fitting within an available space and being manufacturable with materials, such as die cast metal. The fins, for example, may extend above the tops surface between 18 and 22 mm, such as 20.8 mm.

In some embodiments, the fins in each section may be equally spaced from each other. In some embodiments, the fins in each section may be grouped into first and second segments with a space between the segments. The spaces of the sections of the heat dissipation member may be aligned.

Optionally, the connector assembly may include one or more components that occupy space that might otherwise be occupied by the heat dissipation member. The heat dissipation member may be configured to enable such one or more other components, while still providing a desired heat transfer. An example of such a component is a light pipe. The light pipe may include a first end disposed at the rear of the cage, a second end opposite the first end, and a body extending from the first end to the second end through the aligned spaces of the sections of the heat dissipation member. The light pipe may be held by a support member at the first end so as to be adjacent to a light emitting structure on the circuit board. The second end of the light pipe may extend beyond the heat dissipation member for displaying a status of the light emitting structure on the circuit board. The status of the light emitting structure may indicate a status of the connection between the plug connector and the receptacle connector and/or circuit boards. The heat dissipation member may be configured to accommodate such a light pipe while still dissipating sufficient heat to enable operation within a desired thermal range. In one example, the plurality of fins of the heat dissipation member may positioned in two groups, each with fins aligned in parallel on a generally uniform pitch. The two groups of fins may be separated by a gap that is larger than the fin to fin spacing within each group. The light pipe may be positioned in that gap.

In some embodiments, a connector assembly may include a cage having several ports aligned in a row direction. The ports may be configured for accessing to respective channels in the cage and therefore respective receptacle connectors at the other end of the channels. A light pipe assembly may be attached to a side wall of the cage. The light pipe assembly may include several light pipes stacked in a column direction perpendicular to the row direction. Each light pipe may be configured to display a status of a light emitting structure on the circuit board. The status of each light emitting structure may indicate a status of the connection between the plug connector and the receptacle connector in a respective channel and/or circuits on the circuit board.

Such a configuration may enable a high density panel design for some implementations according to the OSFP-XD standard. The circuit board and the connector assembly may be disposed inside a chassis of an electronic device. A panel of the electronic device may have one or more openings aligned with the ports of the connector assembly. The indicating ends of the light pipes of the light pipe assembly may be disposed on one side of the one or more openings on the panel of the electronic device, enabling an efficient use of the panel area.

Such a configuration may enable a high density belly-to-belly design for some implementations according to the OSFP-XD standard. For example, in a belly-to-belly design, two connector assemblies may be mounted on opposite sides of a circuit board. The circuit board and the connector assembly may be disposed inside a chassis of an electronic device. A panel of the electronic device may have one or more openings aligned with the ports of the connector assembly. The indicating ends (i.e., second ends) of the light pipes of the two light pipe assemblies may be disposed on opposite sides of the one or more openings on the panel of the electronic device, enabling an efficient use of the panel area.

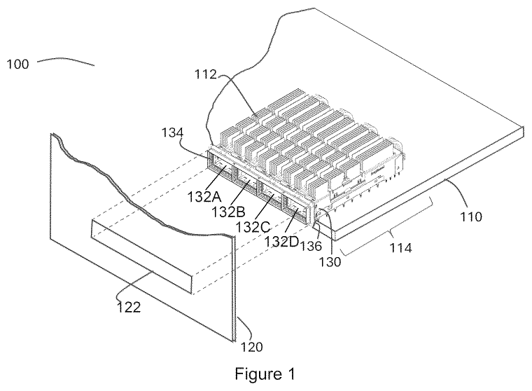

FIG. 1 illustrates an electronic device 100 with a circuit board 110 and a connector assembly 112 for input or output mounted to an edge 114 of the circuit board 110. In this example, the circuit board 110 is a printed circuit board (PCB). The connector assembly 112 is positioned for insertion in an opening 122 of a panel 120 of the electronic device 100, the panel 120 forming an enclosure that will enclose the electronic device 100. In this example, the connector assembly 112 is configured to hold four receptacle connectors, and a cage 130 with four channels 132A, 132B, 132C, and 132D is shown. In the illustrated embodiment, an EMI seal 134 at the opening of each channel of the cage is mounted to all four interior walls at the opening into each channel. In the illustrated embodiment, a separate seal 136 is used between the cage 130 and the opening 122 of the panel 120. In the example, the external seal 136 is a conductive elastomer. The EMI seal 134 may alternatively or additionally be used in place of the seal 136.

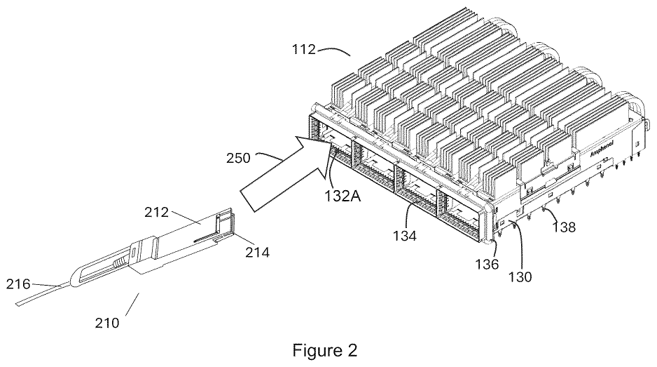

FIG. 2 is a schematic view showing the insertion of a plug connector 210 into cage 130. The plug connector 210 is implemented as a transceiver in this example. As can be seen in FIG. 2, the plug connector 210 terminates a cable 216 and may make connections between cable 216 and components on the circuit board 110 through a receptacle connector of the connector assembly 112. The plug connector is inserted into a channel 132A of the cage 130 in an insertion direction 250 such that a forward end 214 of the plug connector may connect to a receptacle connector (not visible in FIG. 2) at the rear portion of a channel 132 of cage 130.

The plug connector may have a conductive exterior 212 that is contacted at multiple locations along the insertion direction by the EMI seals 134 lining the walls of the channel at its opening. As can be seen in FIG. 2, the cage 130 includes features for connecting the cage to ground structures in a circuit board. In this example, press fits 138 extend from cage 130 for this purpose. In particular, the press fits 138 extend from the bottom of the cage. As the cage 130 is grounded, connecting the exterior 212 of the plug connector to the cage 130 through the EMI seal 134 provides a common ground for the cage and the exterior of the plug connector.

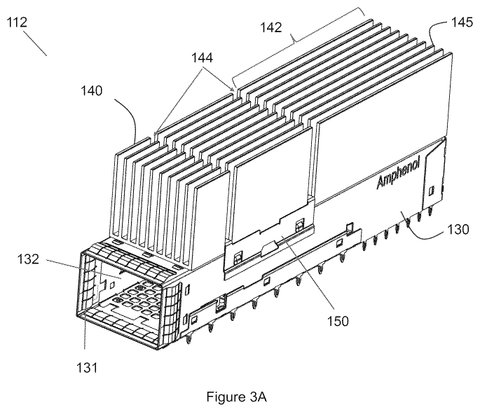

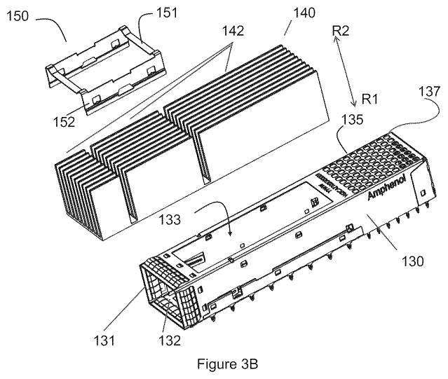

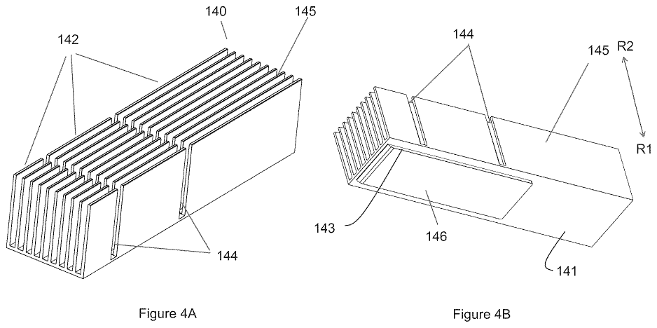

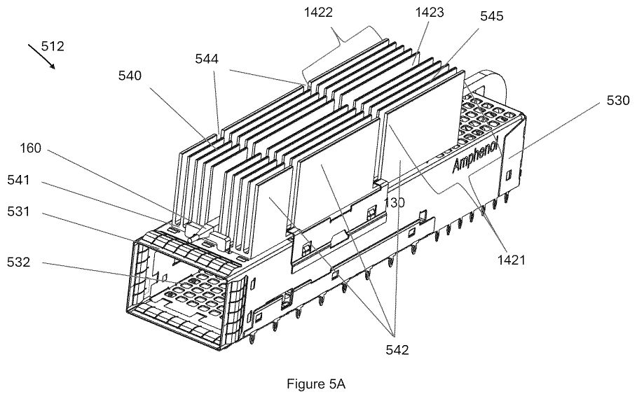

According to aspects of the present disclosure, FIG. 3A illustrates a connector assembly 112 for input or output that can be used in the electronic device 100 of FIG. 1. In the illustrated example, connector assembly 112 is implemented to hold one receptacle connector. FIG. 3B is a partially exploded perspective view of the connector assembly 112 shown in FIG. 3A. FIG. 4A is a top perspective view of a heat dissipation member 140 of the connector assembly 112. FIG. 4B is a bottom perspective view of the heat dissipation member 140.

In the illustrated example, connector assembly 112 comprises a cage 130 comprising walls at a top, bottom, sides and rear of the cage, and a port 131 at a front of the cage and configured to enable access to a channel 132 defined by the walls of the cage 130, with a wall at the top having an opening 133; and a heat dissipation member 140 comprising a base 141 disposed at the wall at the top of the cage 130, a plurality of sections 142 separated by gaps 144, and a contact portion 143 protruding from the base 141 in a first direction R1 into the channel 132 through the opening 133 of the wall at the top of the cage 130. Each of the plurality of sections 142 comprises a plurality of fins 145 protruding from the base 141 in a second direction R2 opposite to the first direction R1; and the heat dissipation member 140 comprises a layer 146 of micro thermal interface material at the contact portion 143.

The connector assembly may comprise a receptacle connector inside the cage, and the receptacle connector may be disposed adjacent the wall at the rear of the cage. During operation, a plug connector is inserted into the channel to mate with the receptacle connector so as to connect to circuits on the circuit board. A contact portion of the heat dissipation member is used for contacting a mating plug connector inside the cage.

In some embodiments, the cage has dimensions according to an OSFP-XD standard. OSFP-XD supports higher data rates, often up to 800 Gbps, which generates more heat during operation. Additionally, the larger form factor of OSFP-XD presents challenges for designing panels. Techniques described herein, including the structure and material composition of components, can provide sufficient heat dissipation to enable high speed, high density connector assemblies for input or output that nonetheless can be economically manufactured and meet the dimensional requirements of an OSFP-XD standard.

The contact portion 143 of the heat dissipation member 140 protrudes from the base 141 in a first direction R1 into a channel 132 through an opening 133 of the wall at the top of the cage 130, for contacting a plug connector that is inserted into the channel 132 through the port 131 and that mates with the receptacle connector. In the illustrated example, the direction in which the plug connector mates with the receptacle connector disposed in the channel of the cage is referred to as the mating direction. The layer 146 coated with micro thermal interface material of the contact portion 143 may provide enhanced thermal performance and durability of the plug connector and the heat dissipation member. Examples of such a micro thermal interface material include BERGQUIST® microTIM mTIM 4028. Such a configuration of the heat dissipation member may provide robustness and resilience to the repeated pull and plug action of insertion devices while delivering good thermal impedance. In this way, there is provided a high speed, high density connector assembly with sufficient heat dissipation.

In some embodiments, each section of the plurality of sections 142 may include fins 145 between nine and eleven. In the example shown in FIGS. 3A to 4B, each section comprises ten fins 145, which may provide desired heat dissipation for the cage with dimensions according to an OSFP-XD standard. In some embodiments, the fins in each section may be equally spaced from each other.

As can be seen from FIGS. 3A to 4B, the plurality of sections 142 is divided into three sections which are separated by two gaps 144. In some embodiments, both the base 141 and the fins 145 may comprise die cast metal. For example, both the base 141 and the fins 145 may be made of die cast metal. In some embodiments, each fin 145 has a height in the range of 18 to 22 mm in a second direction R2. Such fins provide a desired amount of heat dissipation of the connector assembly while nonetheless fitting within an available space. In some embodiments, the base 141 and the fins 145 may be integrally formed.

As shown in FIG. 3A, the heat dissipation member 140 may extend to a wall at the rear of the cage 130 so that heat generated at the rear of the cage can be adequately transferred to the heat dissipation member 140, thereby improving the heat dissipation efficiency of the connector assembly. In some embodiments, the wall at the top of the cage 130 may comprise a region 135 having a plurality of holes 137. In the illustrated example, as can be seen in FIGS. 3A and 3B, the section of the plurality of sections of the heat dissipation member at the rear of the cage is significantly larger than other sections of the heat dissipation member. During the mating and operation of the plug connector and the receptacle connector at the rear of the cage, a large amount of heat may be generated in the rear of the channel, and the heat dissipation area of the heat dissipation member is increased by providing the fins 145 at the section of the plurality of sections 142 of the heat dissipation member 140 above the region 135 larger than the fins 145 at other sections, such that a large amount of heat generated at the rear of the cage 130 due to the mating of the plug connector and the receptacle connector can be efficiently dissipated.

In some embodiments, the cage 130 comprises a copper alloy and a nickel silver plating on the copper alloy; and the heat dissipation member 140 comprises an aluminum alloy and a nickel plating on the aluminum alloy. For example, the cage 130 is made of a copper alloy and a nickel silver plating on the copper alloy; and the heat dissipation member 140 is made of an aluminum alloy and a nickel plating on the aluminum alloy. Such material composition of components can provide sufficient heat dissipation to enable high speed, high density I/O connector assemblies that nonetheless can be economically manufactured and meet the dimensional requirements of an OSFP-XD standard.

In some embodiments, as shown in FIG. 3B, the connector assembly 112 may further comprise a clip 150 comprising strips 151 disposed in the gaps 144 between the plurality of sections of the heat dissipation member 140 and bars 152 connecting the strips 151 and attached to the walls at the sides of the cage 130. In the example shown in FIGS. 3A and 3B, the bars 152 are attached to the wall by hooking to a corresponding aperture of the bars 152 through a hooking member at the wall at the sides of the cage, thereby attaching the heat dissipation member to the cage. In some embodiments, the clip 150 comprises stainless steel. For example, the clip 150 is made of stainless steel. The heat dissipation member is attached to the cage by the clip, thereby providing structural reliability to the connector assembly.

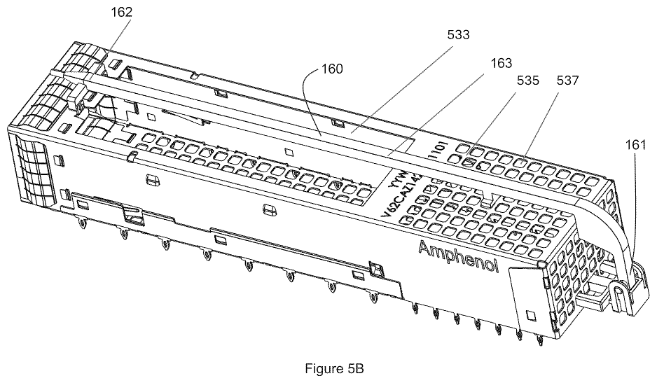

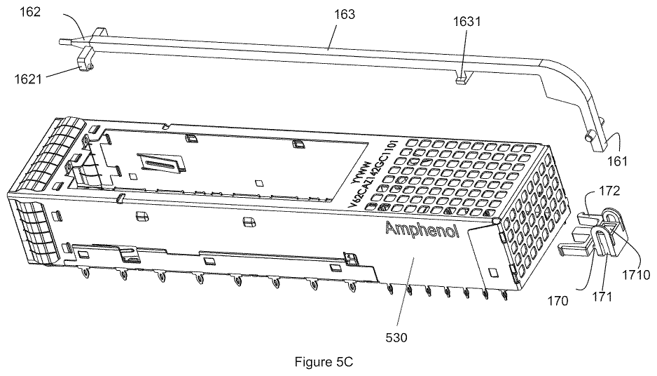

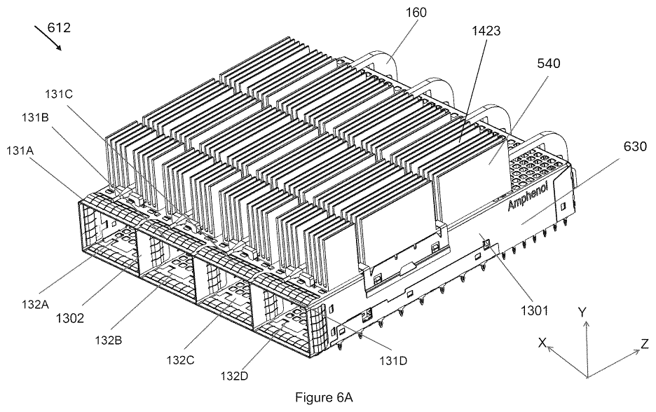

According to aspects of the present disclosure, FIG. 5A illustrates a perspective view of a connector assembly 512 for input or output that can be used in the electronic device of FIG. 1. FIG. 5B is a perspective view of the connector assembly 512 shown in FIG. 5A, with the heat dissipation member and clip hidden. FIG. 5C is partially exploded perspective view of the connector assembly 512 shown in FIG. 5B.

In this example, the connector assembly is configured to hold one receptacle connector. The connector assembly 512 may include a cage 530, a heat dissipation member 540, and a light pipe 160. The configuration of the cage and the heat dissipation member of the connector assembly shown in FIGS. 5A to 5C may share features of the cage and the heat dissipation member shown in FIGS. 3A to 4B, which may not be repeated herein.

As shown in FIG. 5A, each of the plurality of sections 542 of the heat dissipation member 540 comprises a first segment 1421 and a second segment 1422 and a space 1423 therebetween, the first segment 1421 and the second segment 1422 comprising an equal number of fins; the spaces 1423 of the plurality of sections 542 of the heat dissipation member 540 are aligned.

In some embodiments, a light pipe 160 comprises a first end 161 disposed at the wall at the rear of the cage 530, a second end 162 extending beyond the heat dissipation member 540, and a body 163 extending from the first end 161 to the second end 162 through the aligned spaces 1423 of the plurality of sections of the heat dissipation member 540. In some embodiments, the light pipes of the light pipe assembly comprise clear polycarbonate. For example, the light pipes of the light pipe assembly are made of clear polycarbonate.

In some embodiments, the connector assembly 512 further comprises a support member 170 attached to the wall at the rear of the cage 530 and holding the first end of the light pipe 160 to be adjacent to a light emitting structure on the circuit board. The second end 162 of the light pipe 160 extending beyond the heat dissipation member 140 is used for displaying a status of the light emitting structure on the circuit board, thereby facilitating a user to observe the status of the connection. In some embodiments, the status of the light emitting structure may indicate a status of the connection between the plug connector and the receptacle connector and/or circuit boards. The heat dissipation member may be configured to accommodate such light pipe while still dissipating sufficient heat to enable operation of the connector assembly for input or output within a desired thermal range.

In some embodiments, as shown in FIG. 5C, the support member 170 comprises a body 171 having a groove 1710 for holding the first end 161 of the light pipe 160 and a latch 172 extending from the body 171 and attached to, for example, hooked to the wall at the rear of the cage 530.

In some embodiments, as shown in FIG. 5C, both the body 163 and the second end 162 of the light pipe 160 comprise extensions, wherein the extension 1631 of the body 163 and the extension 1621 of the second end 162 are disposed on the wall at the top of the cage 130. The extension 1631 of the body 163 and the extension 1621 of the second end 162 are used for supporting respectively the body 163 and the second end on the wall at the top of the cage.

In some embodiments, the wall at the top of the cage 530 may comprise a region 535 having a plurality of holes 537; and as can be seen from FIG. 5A, the heat dissipation member 540 may extend to the region 135 and end before the wall at the rear of the cage 530, thus providing optimized heat dissipation to the connector assembly.

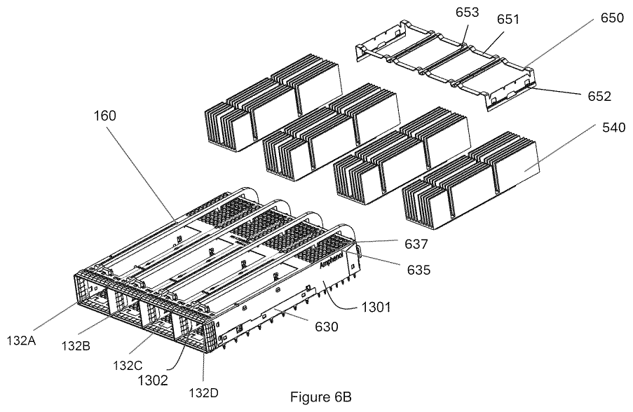

According to aspects of the present disclosure, FIG. 6A illustrates a connector assembly 612 that can be used in the electronic device of FIG. 1. In this example, the connector assembly 612 is configured to hold four receptacle connectors. The connector assembly 612 comprises: a cage 630 comprising outer walls 1301 at a top, bottom, sides and rear of the cage, inner walls 1302 disposed parallel to the outer walls at the sides and dividing interior of the cage into a plurality of channels 132A, 132B, 132C and 132D, and a plurality of port 131A, 131B, 131C and 131D aligned at a front of the cage in a row direction X and configured for accessing to a plurality of channels 132A, 132B, 132C and 132D of the cage; a plurality of heat dissipation members 540; a plurality of light pipes 160; and a clip 650. The heat dissipation member 540 is attached to the cage 630 by the clip 650. The clip 650 comprises strips 651, bars 652, and bars 653 for connecting the strip 651.

In the example shown in FIG. 6A and FIG. 6B, the plurality of heat dissipation members 540 are disposed on an outer wall at the top of the cage 630, and one of the plurality of heat dissipation members 540 is positioned over a corresponding one of the plurality of channels 132A, 132B, 132C, and 132D. Each of the plurality of light pipes extends beyond the heat dissipation member through the aligned spaces 1423 of the plurality of sections of the heat dissipation member 540. The plurality of heat dissipation members are separated from each other by a connecting member of the clip. Other configurations of the cage, the heat dissipation member and the clip shown in FIGS. 6A and 6B may share features of the cage, the heat dissipation member and the clip illustrated in FIG. 5A above, which may not be repeated herein.

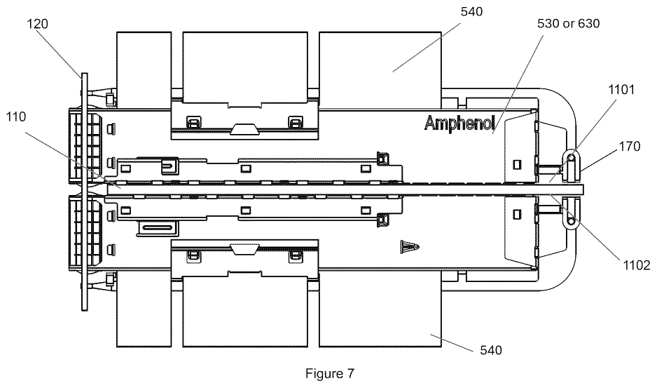

According to aspects of the present disclosure, FIG. 7 illustrates an arrangement structure of a connector assembly for input or output shown in FIG. 5A or FIG. 6A used in a belly-to-belly configuration in the electronic device. In some embodiments, the electronic device may comprise a chassis comprising a panel 120 having one or more openings 122; a circuit board 110 disposed in the chassis, the circuit board 110 comprising a first surface 1101 and a second surface 1102 opposite to the first surface 1101; and a connector assembly configured for insertion into the opening of the panel, the connector assembly comprising a first connector assembly mounted to the first surface 1101 and a second connector assembly mounted to the second surface 1102, the configuration of the first connector assembly and the configuration of the second connector assembly being the same as that of the connector assembly shown in FIG. 5A or FIG. 6A.

In some embodiments, a port(ports) of the cage of the first connector assembly is aligned with one or more openings 122 of the panel 120 of the chassis; each of the light pipes of the first connector assembly includes a first end disposed at the outer wall at the rear of the cage 530 or 630 and a second end extending beyond the heat dissipation member; the number of light pipes of the first connector assembly is configured to be equal to the number of ports of the cage of the first connector assembly. A port(ports) of the cage of the second connector assembly is aligned with one or more openings 122 of the panel 120 of the chassis; each of the light pipes of the second connector assembly includes a first end disposed at the outer wall at the rear of the cage 130 and a second end extending beyond the heat dissipation member. The number of light pipes of the second connector assembly is configured to be equal to the number of ports of the cage of the second connector assembly. In the example shown in FIG. 7, the first connector assembly and the second connector assembly of the electronic device are mounted to the circuit board in a belly-to-belly configuration, thereby providing a high density arrangement structure for the electronic device.

In the configuration of the electronic device shown in FIG. 7, since the configuration of the connector assembly shown in FIG. 5A or FIG. 6A is used, the heat dissipation members 540 are also disposed on opposite sides of the first surface and the second surface of the circuit board, respectively. The outer wall at the top of the cage includes a region 535 or 635 having a plurality of holes 537 or 637, and the heat dissipation member extends to the region and ends before the outer wall at the rear of the cage, such that at least a portion of the plurality of holes of the region is exposed to the internal environment of the electronic device, thereby transferring the heat generated during operation of the mating plug connector and receptacle connector at the rear portion of the cage to the exterior of the cage, providing optimized heat dissipation for the connector assembly.

The configuration of the connector assembly shown in FIG. 7 according to some embodiments of the present application may not only provide a high-density arrangement structure for the electronic device, but may also provide a desired heat dissipation for the electronic device.

In the configuration of the electronic device shown in FIG. 7, the first end of the light pipe of the first connector assembly and the first end of the light pipe of the second connector assembly are both held by corresponding support structures to be adjacent to the light emitting structure of the circuit board, and the second end of the light pipe of the first connector assembly and the second end of the light pipe of the second connector assembly extend beyond the heat dissipation member, thereby displaying a status of the light emitting mechanism of the circuit board, and facilitating a user to observe the status of the connection between the plug connector and the receptacle connector and/or the circuit board.

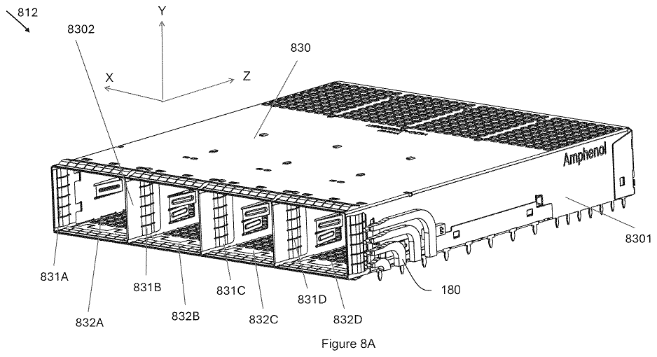

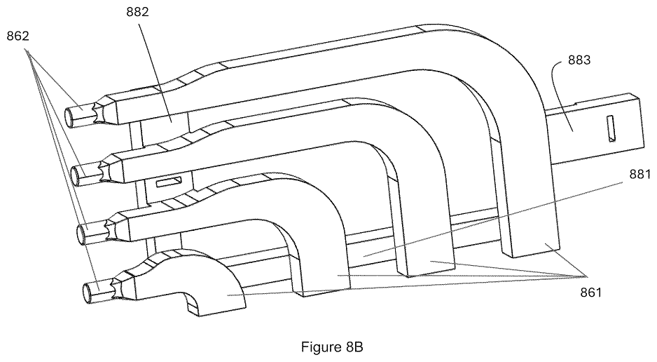

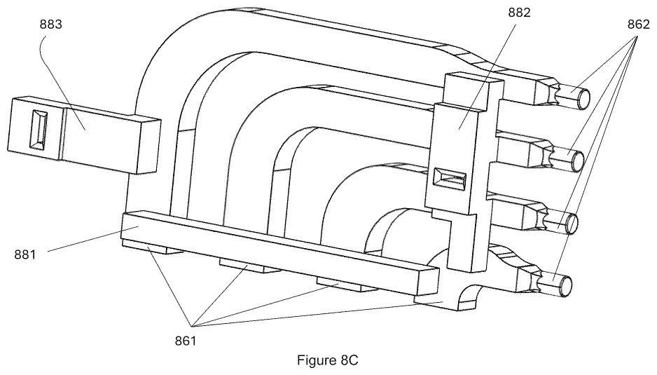

According to aspects of the present disclosure, FIGS. 8A to 8C illustrate a perspective view of a connector assembly for input or output. In this example, the connector assembly 812 is configured to hold four receptacle connectors. As shown in FIG. 8A, the connector assembly 812 comprises: a cage 830 comprising outer walls 8301 at a top, bottom, sides and rear of the cage, inner walls 8302 disposed parallel to the outer walls at the sides and dividing interior of the cage into a plurality of channels 832A, 832B, 832C and 832D, and a plurality of port 831A, 831B, 831C and 831D aligned at a front of the cage in a row direction X and configured for accessing to a plurality of channels 832A, 832B, 832C and 832D of the cage; and a light pipe assembly 180 attached to an outer wall at the side of the cage, the light pipe assembly 180 comprising a plurality of light pipes stacked in a column direction Y perpendicular to the row direction X and separated from each other by equal spacing. Each of the plurality of light pipes has a first end 861 adjacent to the bottom of the cage and a second end 862 adjacent to the front of the cage, the second ends 862 of the plurality of light pipes aligned in a column direction Y, the first ends of the plurality of light pipes aligned in a mating direction Z perpendicular to both the row direction X and the column direction Y. The mating direction refers to a direction in which the plug connector mates with the receptacle connector disposed in the channel of the cage.

The connector assembly may comprise a receptacle connector inside the cage, and the receptacle connector may be disposed adjacent the outer wall at the rear of the cage. During operation, a plug connector may be inserted into the channel to mate with the receptacle connector so as to connect to circuits on the circuit board. In a configuration of a connector assembly including a light pipe assembly, a first end of each light pipe is adjacent to a bottom of the cage and a second end is adjacent to a front of the cage so that a status of a light emitting structure on the circuit board can be displayed. The status of each light emitting structure may indicate a status of the connection between the plug connector and the receptacle connector in a respective channel and/or circuits on the circuit board.

Such a configuration may provide a high density panel design. The circuit board and the connector assembly may be disposed inside a chassis of an electronic device. A panel of the electronic device may have one or more openings aligned with the ports of the connector assembly. The indicating ends (i.e., second end) of the light pipes of the light pipe assemblies may be disposed on one side of the one or more openings on the panel of the electronic device, enabling an efficient use of the panel area.

As shown in FIGS. 8B and 8C, the light pipe assembly 180 comprises a first rod 881 connecting the first ends 861 of the plurality of light pipes; a second rod 182 connecting the second ends 862 of the plurality of light pipes; and a third rod 883 extending from a light pipe of the plurality of light pipes and attached to the outer wall at the side of the cage. In some embodiments, the light pipes of the light pipe assembly comprise clear polycarbonate. For example, the light pipes of the light pipe assembly are made of clear polycarbonate. In some embodiments, the light pipe is configured to display a status of a light emitting structure of the circuit board. The status of the light emitting structure may indicate a status of the connection between the plug connector and the receptacle connector in a respective channel and/or circuits of the circuit board. In some embodiments, the cage may have dimensions according to an OSFP-XD standard.

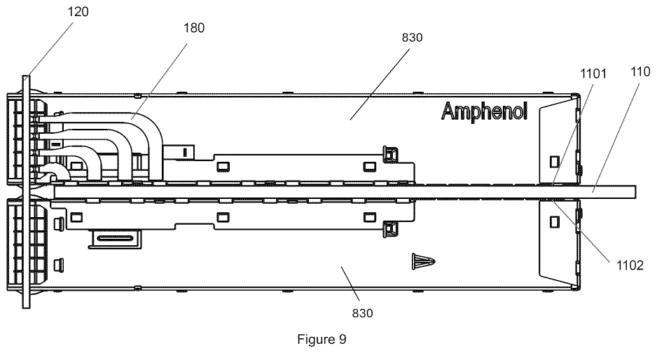

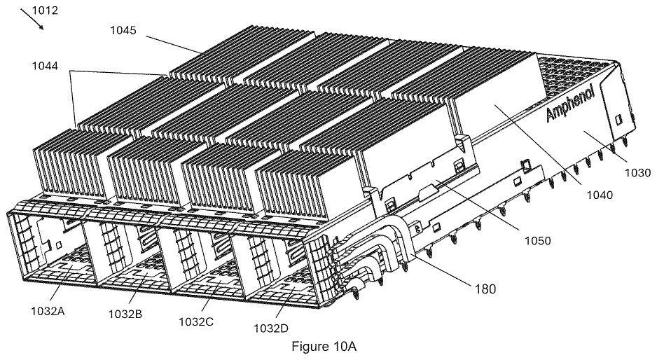

FIG. 9 illustrates an arrangement structure for the connector assembly shown in FIG. 8A used in a belly-to-belly configuration of the connector assembly in the electronic device. In some embodiments, the electronic device may comprise a chassis comprising a panel 120 having one or more openings 122; a circuit board 110 disposed in the chassis, the circuit board 110 comprising a first surface 1101 and a second surface 1102 opposite to the first surface 1101; and a connector assembly configured for insertion into the opening of the panel 120, the connector assembly 112 comprising a first connector assembly mounted to the first surface 1101 and a second connector assembly mounted to the second surface 1102, the configuration of the first connector assembly and the configuration of the second connector assembly being the same as that of the connector assembly shown in FIG. 8A.

In the example shown in FIG. 9, the bottom of the cage of the first connector assembly is mounted to the first surface 1101 of the circuit board, the first end of each light pipe of the light pipe assembly of the first connector assembly is disposed to be adjacent to the bottom of the cage, and the second end is adjacent to the front of the cage and is used to display a status of the light emitting structure of the circuit board; the bottom of the cage of the second connector assembly is mounted to the second surface 1102 of the circuit board, the first end of each light pipe of the light pipe assembly of the second connector assembly is disposed to be adjacent to the bottom of the cage, and the second end is adjacent to the front of the cage and is used to display a status of the light emitting structure of the circuit board.

The first connector assembly and the second connector assembly may comprise a receptacle connector inside a corresponding cage, and the receptacle connector may be disposed adjacent to the outer wall at the rear of the corresponding cage. During operation, a plug connector is inserted into the channel to mate with the corresponding receptacle connector so as to connect to circuits on the circuit board. Thus, the status of each light emitting structure of the circuit board may indicate a status of the connection between the plug connector and the receptacle connector in a respective channel and/or circuits on the circuit board. The second end of the light pipe in the light pipe assembly of the first connector assembly and the second end of the light pipe in the light pipe assembly of the second connector assembly are disposed on opposite sides of the one or more openings of the panel, so as to efficiently utilize the panel area and facilitate a user to observe the status of the connection. The belly-to-belly configuration of the connector assembly of the electronic device shown in FIG. 9 provides a high density arrangement structure for the electronic device.

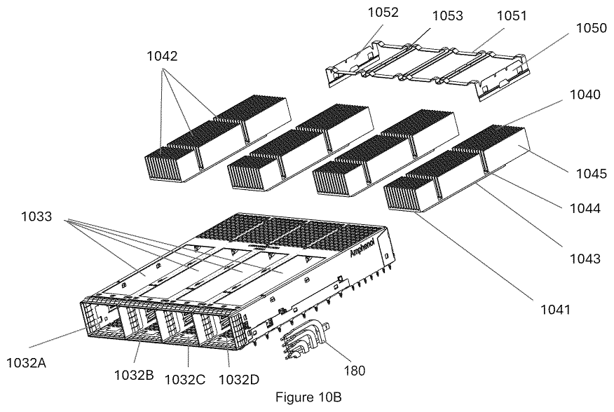

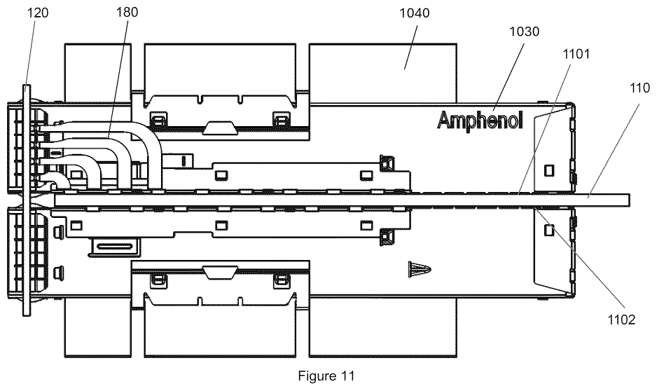

According to aspects of the present disclosure, FIGS. 10A and 10B illustrate a connector assembly for input or output. Unlike the connector assembly shown in FIG. 8A, the outer wall at the top of the cage includes a plurality of openings 1033 each above a corresponding channel of the plurality of channels 1032A, 1032B, 1032C, and 1032D, as shown in FIG. 10B. In this example, the connector assembly 1012 may further comprise: a plurality of heat dissipation members 1040, each of which comprises a base 1041 disposed at the top of the cage, a plurality of sections 1042 separated by gap 1044, and a contact portion 1043 protruding from the base 1041 in a first direction R1 into a respective channel of the plurality of channels 1032A, 1032B, 1032C, and 1032D through a respective opening of the plurality of openings 1033 at the outer wall at the top of the cage. Each of the plurality of sections 1042 comprises a plurality of fins 1045 protruding from the base 1041 in a second direction R2 opposite to the first direction R1.

In some embodiments, the cage comprises a copper alloy and a nickel silver plating on the copper alloy. For example, the cage is made of a copper alloy and a nickel silver plating on the copper alloy. Each of the plurality of the heat dissipation members comprises an aluminum alloy, a nickel plating on the aluminum alloy, and a layer of micro thermal interface material at the contact portion. A contact portion of the heat dissipation member contacts a mating plug connector inside the cage. The layer of micro thermal interface material of the contact portion may be manufactured to enhance thermal performance and durability of the plug connector and the heat dissipation member. Examples of such a micro thermal interface material include BERGQUIST® microTIM mTIM 4028. Such configuration may provide robustness and resilience to the repeated pull and plug action resulting from inserting into devices while delivering good thermal impedance.

Further, the connector assembly further comprises a clip 1050 comprising strips 1051 disposed in the gaps 1044 between the plurality of sections of the plurality of heat dissipation members, bars 1052 connecting the strips 1051 and attached to the outer walls at the sides of the cage 1030, and a bar 1053 for connecting the strips 1051. The plurality of heat dissipation members 1040 are attached to the cage 1030 by the clip 1050, thereby providing firm attachment for the heat dissipation member 1040.

FIG. 11 illustrates an arrangement structure for connector assemblies for input or output shown in FIGS. 10A and 10B used in a belly-to-belly configuration of the connector assembly in the electronic device, according to some exemplary embodiments. In some embodiments, the electronic device comprises a chassis comprising a panel 120 having one or more openings 122; a circuit board 110 disposed in the chassis, the circuit board 110 comprising a first surface 1101 and a second surface 1102 opposite to the first surface 1101; and a connector assembly configured for insertion into the opening of the panel, the connector assembly 112 comprising a first connector assembly mounted to the first surface 1101 and a second connector assembly mounted to the second surface 1102, the configuration of the first connector assembly and the configuration of the second connector assembly being the same as that of the connector assembly shown in FIGS. 10A and 10B.

In the example shown in FIG. 11, the bottom of the cage of the first connector assembly is mounted to the first surface 1101 of the circuit board, a first end of each light pipe of the light pipe assembly of the first connector assembly is disposed to be adjacent to the bottom of the cage, and a second end is adjacent to the front of the cage and is used to display a status of the light emitting structure of the circuit board. A first end of each light pipe of the light pipe assembly of the second connector assembly is disposed to be adjacent to the bottom of the cage, and a second end is adjacent to the front of the cage and is used to display a status of the light emitting structure of the circuit board.

The first connector assembly and the second connector assembly may comprise a receptacle connector inside a corresponding cage, and the receptacle connector may be disposed adjacent to the outer wall at the rear of the corresponding cage. During operation, a plug connector is inserted into the channel to mate with the corresponding receptacle connector so as to connect to circuits on the circuit board. Thus, the status of each light emitting structure of the circuit board may indicate a status of the connection between the plug connector and the receptacle connector in a respective channel and/or circuits on the circuit board. The second end of the light pipe in the light pipe assembly of the first connector assembly and the second end of the light pipe in the light pipe assembly of the second connector assembly are disposed on opposite sides of the one or more openings of the panel, so as to efficiently utilize the panel area. The belly-to-belly configuration of the connector assembly of the electronic device shown in FIG. 11 provides a high density arrangement structure for the electronic device, and the provision of the heat dissipation member also provides a desired heat dissipation.

Having thus described several aspects of several embodiments of a connector assembly and an electronic device including the connector assembly, it is to be appreciated that various alterations, modifications, and improvements will readily occur to those skilled in the art. Such alterations, modifications, and improvements are intended to be part of this disclosure, and are intended to be within the spirit and scope of the application. While the present teachings have been described in conjunction with various embodiments and examples, it is not intended that the present teachings be limited to such embodiments or examples. On the contrary, the present teachings encompass various alternatives, modifications, and equivalents, as will be appreciated by those of skill in the art.

Such alterations, modifications, and improvements are intended to be part of this disclosure and are intended to be within the spirit and scope of the invention. Further, though advantages of the present invention are indicated, it should be appreciated that not every embodiment of the invention will include every described advantage. Some embodiments may not implement any features described as advantageous herein and in some instances. Accordingly, the foregoing description and drawings are by way of example only.

Various aspects of the present invention may be used alone, in combination, or in a variety of arrangements not specifically discussed in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Also, the present application may be embodied as a method, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

Also, circuits and modules depicted and described may be reordered in any order, and signals may be provided to enable reordering accordingly.

Use of ordinal terms such as “first,” “second,” “third,” etc., in the claims to modify a claim element does not by itself connote any priority, precedence, or order of one claim element over another claim element, nor does it indicate the temporal order of performing method actions, but are used merely as labels to distinguish one claim element having a certain name from another element having a same name (but for use of the ordinal term) to distinguish the claim elements.

All definitions, as defined and used herein, should be understood to be over dictionary definitions, definitions in documents incorporated by reference, and/or ordinary meanings of the defined terms.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

What is claimed is:

1. A connector assembly comprising:
a cage comprising walls at a top, bottom, sides and rear, and a port at a front and configured to enable access to a channel, a top wall having an opening; and
a heat dissipation member comprising a base disposed at the top of the cage, a plurality of sections separated by gaps, and a contact portion protruding from the base in a first direction into the channel through the opening of the top wall, wherein:
each of the plurality of sections comprises a plurality of fins protruding from the base in a second direction opposite to the first direction; and
the heat dissipation member comprises a layer of micro thermal interface material at the contact portion.

2. The connector assembly of claim 1, wherein:
the cage has dimensions according to an OSFP-XD standard.

3. The connector assembly of claim 2, wherein:
each of the plurality of sections has ten fins protruding from the base in the second direction; and
both the base and the ten fins comprise die cast metal.

4. The connector assembly of claim 3, wherein:
each fin has a height in a range of 18 to 22 mm in the second direction.

5. The connector assembly of claim 4, wherein:
the heat dissipation member extends to the rear of the cage.

6. The connector assembly of claim 1, wherein:
the cage comprises a copper alloy and a nickel silver plating on the copper alloy; and
the heat dissipation member comprises an aluminum alloy and a nickel plating on the aluminum alloy.

7. The connector assembly of claim 6, further comprising:
a clip comprising strips disposed in the gaps between the plurality of sections of the heat dissipation member and bars connecting the strips and attached to side walls of the cage,
wherein the clip comprises stainless steel.

8. The connector assembly of claim 1, wherein:
each of the plurality of sections of the heat dissipation member comprises a first segment, a second segment, and a space therebetween, the first segment and the second segment comprising an equal number of fins;
the spaces of the plurality of sections of the heat dissipation member are aligned; and
the connector assembly comprises a light pipe having a first end disposed at the rear of the cage, a second end extending beyond the heat dissipation member, and a body extending from the first end to the second end through the aligned spaces of the plurality of sections of the heat dissipation member.

9. The connector assembly of claim 8, further comprising:
a support member attached to a rear wall of the cage and holding the first end of the light pipe.

10. The connector assembly of claim 9, wherein:
the support member comprises a body having a groove for holding the first end of the light pipe and a latch extending from the body of the support member and hooked to the rear wall of the cage.

11. The connector assembly of claim 10, wherein:
both the body and the second end of the light pipe comprise extensions disposed on the top wall of the cage.

12. The connector assembly of claim 8, wherein:
the top wall of the cage comprises a region having a plurality of holes; and
the heat dissipation member extends to the region and ends before the rear of the cage.

13. A connector assembly comprising:
a cage comprising outer walls at a top, bottom, sides and rear, inner walls disposed parallel to the outer walls at the sides, and a plurality of ports aligned at a front in a row direction and configured for accessing to a plurality of channels; and
a light pipe assembly attached to an outer wall at a side of the cage, the light pipe assembly comprising a plurality of light pipes each having a first end adjacent the bottom of the cage and a second end adjacent the front of the cage, the second ends of the plurality of light pipes aligned in a column direction perpendicular to the row direction, the first ends of the plurality of light pipes aligned in a mating direction perpendicular to both the row direction and the column direction.

14. The connector assembly of claim 13, wherein:
the light pipe assembly comprises:
a first rod connecting the first ends of the plurality of light pipes,
a second rod connecting the second ends of the plurality of light pipes, and
a third rod extending from a light pipe of the plurality of light pipes and attached to the outer wall at the side of the cage;
an outer wall at the top of the cage comprises a plurality of openings above respective channels of the plurality of channels; and
the connector assembly further comprises a plurality of heat dissipation members, each of the plurality of heat dissipation members comprising a base disposed at the top of the cage, and a contact portion protruding from the base in a first direction into a respective channel of the plurality of channels through a respective opening of the plurality of openings.

15. The connector assembly of claim 13, wherein:
The plurality of light pipes of the light pipe assembly comprise clear polycarbonate.

16. The connector assembly of claim 13, wherein:
the cage has dimensions according to an OSFP-XD standard.

17. The connector assembly of claim 14, wherein:
the cage comprises a copper alloy and a nickel silver plating on the copper alloy; and
each of the plurality of heat dissipation members comprises an aluminum alloy, a nickel plating on the aluminum alloy, and a layer of micro thermal interface material at the contact portion.

18. The connector assembly of claim 14, wherein:
each of the plurality of heat dissipation members has a plurality of sections separated by gaps, each of the plurality of sections comprising a plurality of fins protruding in a second direction opposite to the first direction; and
the connector assembly further comprises a clip comprising strips disposed in the gaps between the plurality of sections of the plurality of heat dissipation members and bars connecting the strips and attached to the outer walls at the sides of the cage.

19. A connector assembly comprising:
a cage comprising a plurality of ports aligned in a row direction;
a plurality of heat dissipation members, each of the plurality of heat dissipation members comprising a base disposed at a top of the cage; and
a plurality of light pipes, each of the plurality of light pipes comprising a first end aligned in a mating direction, and a second end adjacent the plurality of ports of the cage and aligned in a column direction perpendicular to both the row direction and the mating direction,

20. The connector assembly of claim 19, wherein:
a number of the plurality of light pipes is configured to be equal to a number of the plurality of ports of the cage.
